(19) United States
(12) Patent Application Publication
(10) Pub. No.: US 2005/0285269 A1
(43) Pub. Date: Dec. 29, 2005

(54) Substantially void free interconnect formation

(76) Inventors: Yang Cao, Beaverton, OR (US); Robert I. Wu, Portland, OR (US); Yue Ma, Hillsboro, OR (US); Chia-Hong Jan, Portland, OR (US); Vinay B. Chikarmane, Portland, OR (US); Rajiv Rastogi, Portland, OR (US)

Correspondence Address: SCHWABE, WILLIAMSON & WYATT, P.C.;PACWEST CENTER, SUITE 1900, 1211 SW FIFTH AVENUE, PORTLAND, OR, 97204, US

(21) Appl. No.: 10/881,778

(22) Filed: Jun. 29, 2004

(51) Int. Cl. H01L 21/425; H01L 21/4763; H01L 21/44; H01L 23/48; H01L 23/52; H01L 29/40

(52) U.S. Cl. 257/758; 438/638; 438/533

(57) ABSTRACT

A die is provided with an insulation layer and an interconnect. The interconnect has been recrystallized to reduce void content.

### BACKGROUND OF THE INVENTION

1. Field of the Invention

Embodiments of the present invention relate to, but are not limited to, electronic devices, and in particular, to the field of interconnects.

2. Description of Related Art

Integrated circuits use conductive contacts and interconnects to wire together individual devices on a semiconductor substrate, or to conduct input into and output from the integrated circuits. Interconnects may include metals such as aluminum, copper, silver, gold, tungsten and their alloys. A typical method of forming an interconnect is a damascene process that involves forming an interconnect recess in a dielectric or insulation layer. The interconnect recess (hereinafter referred to as “recess”) may also be lined with a diffusion barrier layer. Often, a conductive seed material is then deposited in the recess. Thereafter, the conductive material is introduced into the recess. The conductive material is then typically planarized.

In the current state of integrated circuit technology, highly packed integrated circuit devices are currently being manufactured. One such densely populated circuit device is known as an ultra large scale integration (ULSI) device that includes countless minute components including very small interconnects. These interconnects may be so small that, in some cases, the interconnects will have a width of less than 100 nanometers.

### BRIEF DESCRIPTION OF THE DRAWINGS

The present invention will be described by way of exemplary embodiments, but not limitations, illustrated in the accompanying drawings in which like references denote similar elements, and in which:

FIG. 1A illustrates a side split view of an exemplary void free interconnect according to some embodiments;

FIG. 1B illustrates a plan view of a trench and via according to some embodiments;

FIG. 1C illustrates a side view of multiple ILD layers according to some embodiments;

FIG. 2 illustrates a process for forming a recrystallized interconnect according to some embodiments;

FIGS. 3A to 3H illustrate the interconnect at different stages of the process of FIG. 2 according to some embodiments; and

FIG. 4 is a block diagram of an example system, according to some embodiments of the invention.

### DETAILED DESCRIPTION OF ILLUSTRATIVE EMBODIMENTS

In the following description, for purposes of explanation, numerous details are set forth in order to provide a thorough understanding of the disclosed embodiments of the present invention. However, it will be apparent to one skilled in the art that these specific details are not required in order to practice the disclosed embodiments of the present invention. In other instances, well-known electrical structures and circuits are shown in block diagram form in order not to obscure the disclosed embodiments of the present invention.

The following description includes terms such as on, onto, over, top, and the like, that are used for descriptive purposes only and are not to be construed as limiting. That is, these terms are terms that are relative only to a point of reference and are not meant to be interpreted as limitations but are instead, included in the following description to facilitate understanding of the various aspects of the invention.

According to various embodiments of the invention, formation of voidless or substantially voidless interconnects is provided. For these embodiments, an interconnect may be defined as but is not limited to a via, a trench or trace, a plug or a combination thereof. The interconnects may be located among multiple dielectric layers that may be stacked one on top of another on, for example, a die or wafer substrate. In various embodiments, a die or a wafer containing interconnects that have bottom widths of less than about 90 nanometers (nm) may be formed with less than 70 percent of the interconnects having voids, and in some embodiments, less than 1 percent of the interconnects having voids.

For the embodiments, voids or seams may be formed within an interconnect during the formation of the interconnect using, for example, a single or dual damascene process. The presence of such voids or seams in interconnects may have dire consequences since these voids or seams may eventually lead to the premature failure of the interconnects as a result of electromigration. In some embodiments, formation of a void or voids in interconnects may be more likely when the interconnects being formed are relatively small such as an interconnect having a bottom width of less than about 90 nm and/or have an aspect ratio greater than 3.5. In various embodiments, the void or voids may be eliminated by recrystallizing the conductive material that is used to form the interconnect. In some embodiments, recrystallization of the conductive material may be achieved by localized annealing using, for example, rapid laser annealing.

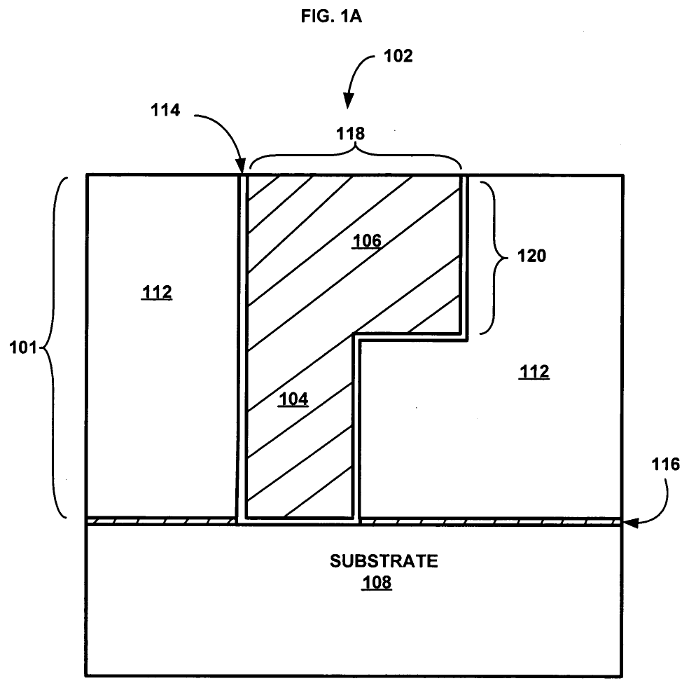

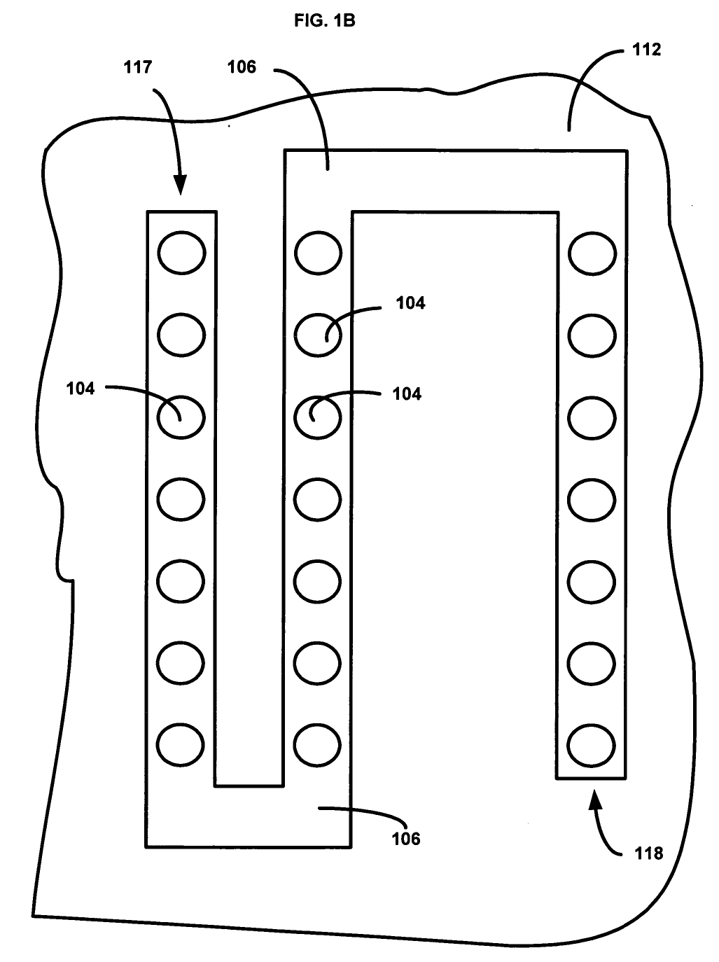

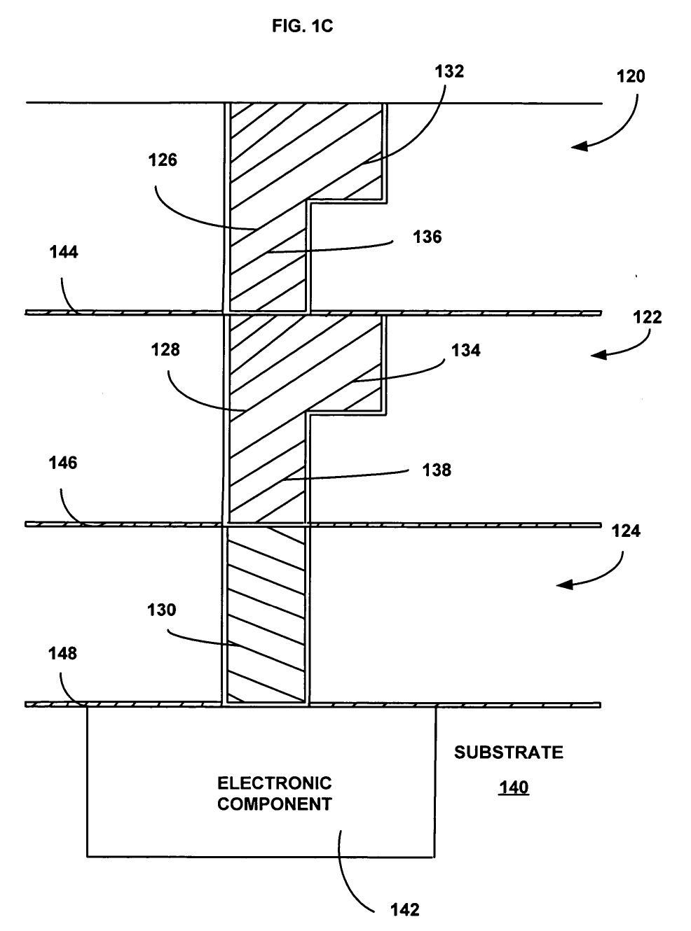

Referring to FIG. 1A which depicts an interconnect 102 that includes a via 104 and a trench 106 according to some embodiments. For the embodiments, the interconnect 102 is embedded in an insulation layer 112. The interconnect 102 and the insulation layer 112 are part of an interlayer dielectric (ILD) layer 101 that is on top of a substrate 108. Between the insulation layer 112 and the interconnect 102 is a diffusion barrier layer 114. Disposed between the substrate 108 and the ILD layer 101 is an etch stop layer 116.

In various embodiments, the substrate 108 may be, for example, part of a die or wafer such as a ULSI chip. The insulation layer 112 may be any type of insulation or dielectric material that may be suitable for electrically isolating the interconnect 102. Although not depicted, such an insulation layer 112 may include a plurality of interconnects. Examples of insulation materials include but are not limited to interlayer dielectrics (ILD) and low-k dielectrics. The barrier layer 114 is typically used to prevent or hinder the diffusion of conductive (e.g., interconnect) material into the surrounding material (e.g., insulation layer 112) but does not prevent the interconnect 102 from electrically coupling with other components. Etch stop layer 116 may serve as etch stop during the patterning of a damascene structure without attacking the underlying interconnect 102 or substrate 108. This etch stop layer 116 may also act as a diffusion barrier to prevent or hinder the diffusion of conductive (e.g., interconnect) material into the surrounding material and/or underlying substrate.

When an interconnect, such as the one depicted in FIG. 1A, is incorporated into a highly packed device such as a ULSI device, the interconnect may have relatively small dimensions. For example, in some embodiments, the width 118 of the trench 106 may be less than 110 nanometers (nm) at its widest point which, in some cases, is at the mouth of the trench 106—the width of an interconnect may be defined as the width of the interconnect excluding the barrier layer 114. The aspect ratio (AR) of the trench 106, which is equal to the height 120 of the trench 106 divided by the width 118 of the trench 106, may be greater than 2.0 after a chemical mechanical polishing (CMP) process has been performed on the trench 106 and greater than 3.5 pre-CMP. Similarly, some vias, such as the via 104 depicted in FIG. 1A, may also have similar dimensions and have similar AR values. These “small” interconnects may be susceptible to void formation particularly during interconnect formation.

Note that the interconnect 102 in FIG. 1A is a depiction of a specific type of interconnect and is provided for illustrative purpose only. Note further that the interconnect 102 is not drawn to scale and that many variations are possible. For example, although the width 118 of the trench 106 appears to be constant from the top of the trench to the bottom of the trench, in various embodiments, the trench 118 may have a more tapered (e.g., narrower) width towards the bottom of the trench. For example, some trenches have widths of about 110 nm at the mouth of the trench but may have a width of less than 90 nm at the bottom of the trench. Those skilled in the art may recognize that many types of interconnects are possible and that they may come in many different sizes, shapes and compositions. Therefore, references to the “interconnect” in the following description is meant to cover all interconnects.

FIG. 1B depicts a plan view of the ILD layer 101 of FIG. 1A according to various embodiments. For the embodiments, the trench 106, which is depicted here absent the interconnect material, is embedded in an insulation layer 112. At the bottom of the trench 106 are multiple vias 104. The trench 106, when fully formed, is metal or conductive lines that run within an ILD layer 101 depicted in FIG. 1A. Although the trench 106 in this embodiment is depicted as being made of straight trench lines, in other embodiments, a trench may be comprised of curved trench lines.

Referring now to FIG. 1C, which depicts multiple ILD layers on top of a substrate in accordance with some embodiments. In various embodiments, the ILD layers may be metallization layers that may be numbered as M1, M2, M3 and the like. For the embodiments, each of the ILD layers 120 to 124 have substantially void free interconnects 126 to 130. The interconnects 126 and 128 for the top two interconnect layers 120 and 122 each have a trench 132 and 134 and a via 136 and 138. In the third interconnect layer 124, which is on top of a substrate 140, is an interconnect 130 that is a plug such as a tungsten plug. Embedded within the substrate 140 is an electronic component 142, such as transistor, that is electrically coupled to the plug interconnect 130. Between each of the interconnect layers 120 to 124 and the substrate 140 are diffusion barrier (“barrier”) layers 144 to 148.

In various embodiments, each of the interconnect layers 120 to 124 may be formed one layer at a time. For example, in some damascene processes, the bottom interconnect layer 124 may be formed first on the substrate 140 before forming another interconnect layer 122 on top of the bottom interconnect layer 124. Similarly, the top interconnect layer 120 is formed on the middle interconnect layer 122 only after the middle interconnect layer 122 has already been formed on top of the bottom interconnect layer 124. For these embodiments, each of the interconnects 126 to 130 may be recrystallized before the next interconnect layer is formed on top of the interconnect layer that the recrystallized interconnect belongs to. In various embodiments, the recrystallization of an interconnect 126 to 130 may eliminate or at least reduce the voids or seams that may form during the formation of the interconnects 126 to 130.

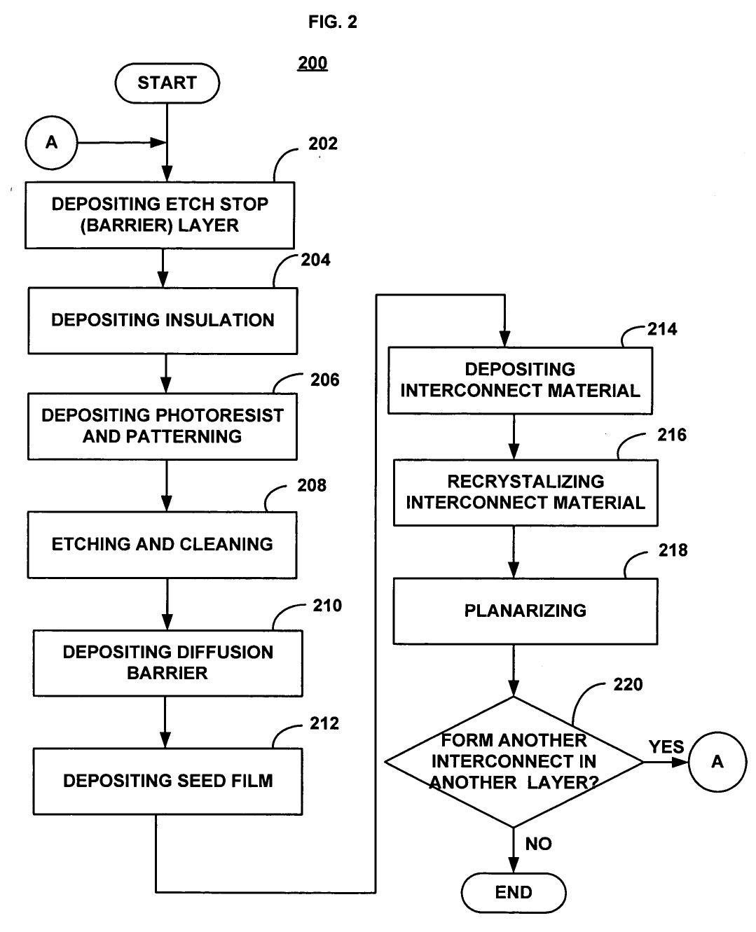

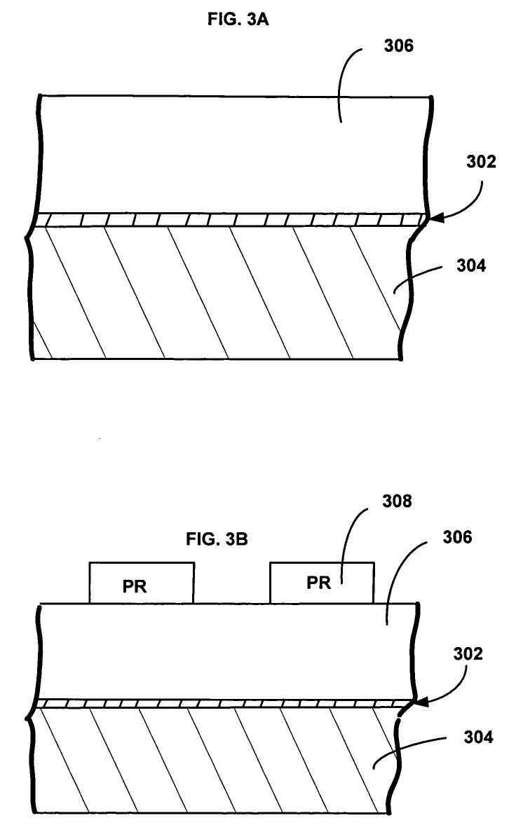

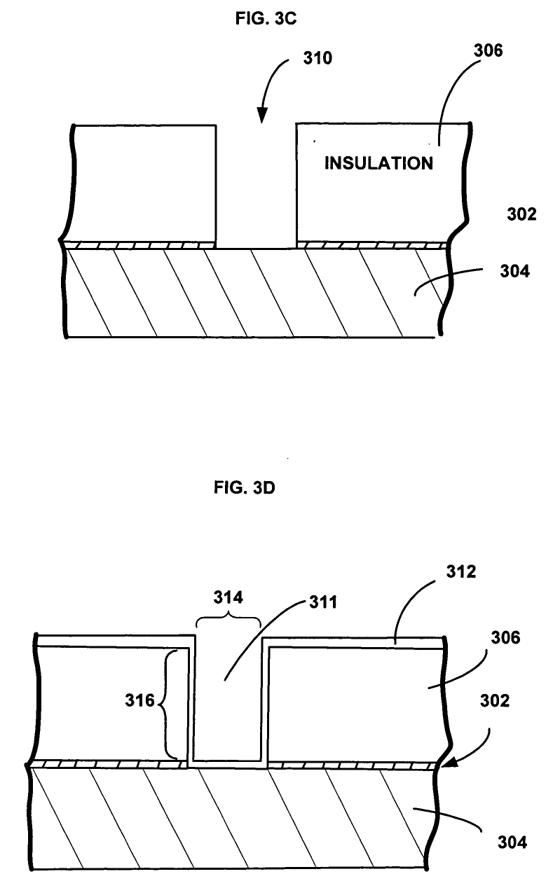

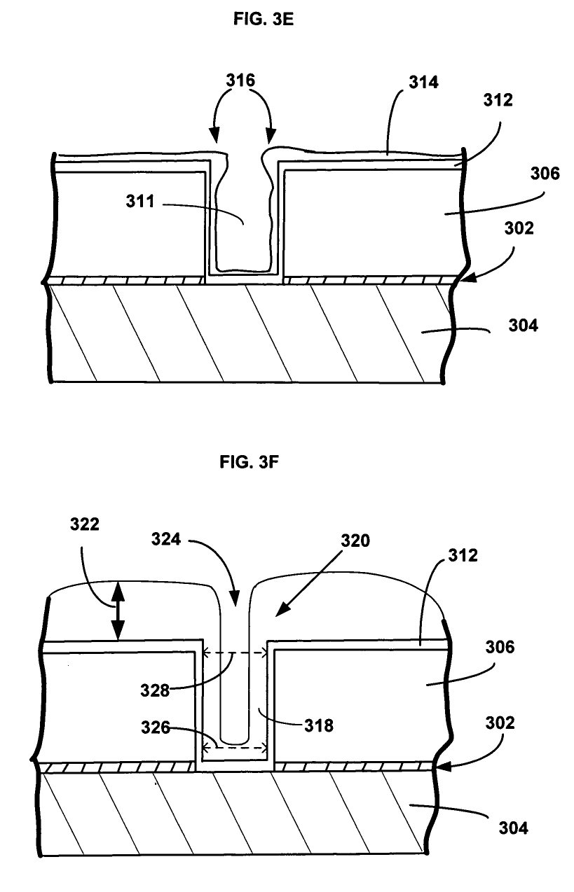

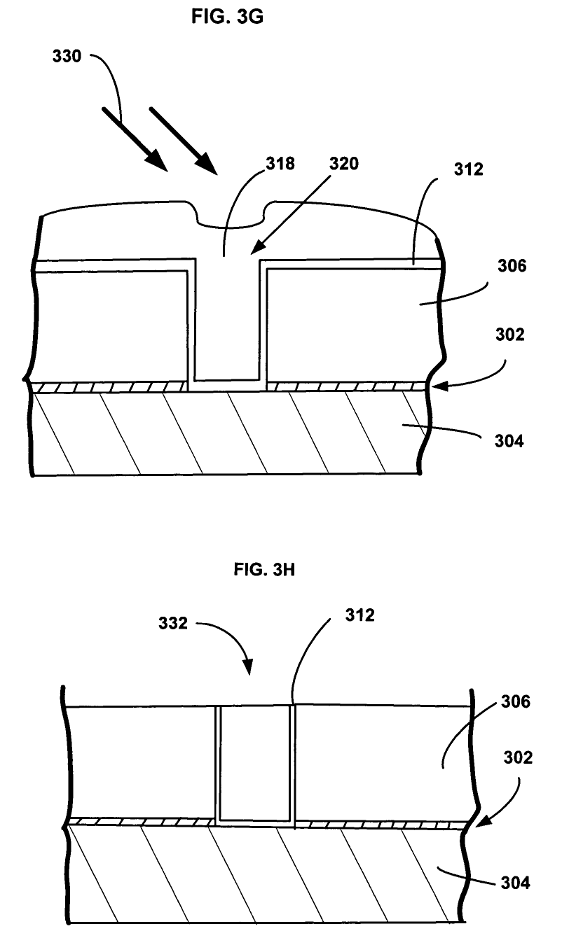

FIG. 2 depicts a process for forming a recrystallized interconnect of an ILD layer according to some embodiments. In various embodiments, the resulting recrystallized interconnect may be a voidless or substantially voidless interconnect. Although the process 200 is associated with a single or dual damascene scheme, various aspects of the process 200 may be used with other processes for forming interconnects. FIGS. 3A to 3H are cross-sectional views of structures associated with the different stages of the process depicted in FIG. 2. The process 200 may be repeated multiple times in order to form a plurality of substantially voidless interconnects in a single or multiple insulation layers of a wafer or die.

The process 200 may begin when an etch stop/barrier (“barrier”) layer 302 is deposited onto a base 304 at block 202 in accordance with various embodiments (see FIG. 3A). For these embodiments, the etch stop layer 302 may serve two functions, as an etch stop and as a diffusion barrier layer. The barrier layer 302 may be comprised of materials such as but are not limited to silicon nitride, silicon carbide, silicon oxycarbide, silicon oxynitride, and the like. If the barrier layer 302 is comprised of silicon nitride, a chemical vapor deposition process may be used to form the barrier layer 302. In one embodiment, the barrier layer 302 is deposited to a thickness in the range from about 30 to about 200 angstroms.

In various embodiments, the base 304 may be a die or wafer substrate or an ILD layer. If the base 304 is a substrate then it may include, among other things, semiconductor devices, such as but are not limited to, active and passive devices such as transistors, capacitors, resistors, diffused junctions, gate electrodes, local interconnects, and the like. If the base 304 is an ILD layer than it may include, among other things, one or more interconnects.

According to various embodiments, an insulation layer 306 may be deposited or formed on the barrier layer 302 at block 204 (see FIG. 3A). The insulation layer 306 may be comprised of but is not limited to organic polymers such as polyimides, parylenes, polyarylethers, polynaphthalenes, polyquinolines, bisbenzocyclobutene, polyphenylene, polyarylene, their copolymers or their porous polymers. Other materials that may be used in forming the insulation layer 306 includes various oxides such as silicon dioxide, fluoro-silicate (SiOF), silicon oxynitride, silicon carbide, carbon doped oxides, and the like. The material used for forming the insulation layer 306 may have a low dielectric constant such as less than about 3.5. In some embodiments, the material may have a dielectric constant of between about 1.0 and about 3.0. The insulation layer 306 may be formed using, for example, various techniques such as but are not limited to chemical vapor deposition or spin-on processes.

After depositing or forming the insulation layer 306 on the barrier layer 302, a photoresist layer 308 may be deposited and patterned on top of the insulation layer 306 to define an interconnect recess for receiving a subsequently deposited conductive (herein “interconnect”) material at block 206 (see FIG. 3B). The photoresist layer 308 may be patterned using, for example, a photolithographic process that includes masking the layer of photoresist, exposing the masked layer to light, and then developing the unexposed portions.

Once the photoresist layer 308 is formed and patterned, the exposed portion of the insulation layer 306 may be etched to form an interconnect recess 310 and the photoresist 308 may be removed at block 208 (see FIG. 3C) in accordance with various embodiments. If the insulation layer 306 comprises a polymer-based film, a plasma formed from a mixture of oxygen, nitrogen, and carbon monoxide may be used to perform the etching process. In various embodiments, the initial interconnect recess 310 that is formed may reach down to the support layer 304. Following the etching process, the photoresist layer 308 may be removed using, for example, any photoresist removal technique.

Next, a diffusion barrier (“barrier”) layer 312 may be deposited or formed on the insulation layer 306 and in the initial interconnect recess 310 at block 210 (see FIG. 3D). After depositing the barrier layer 312, a narrower interconnect recess 311 is formed. The barrier layer 312 may inhibit the diffusion of atoms of the conductive interconnect material that will be used to fill the interconnect recess 311 into the surrounding insulation layer 306. The barrier layer 312 may be comprised of materials such as but are not limited to tantalum nitride, tantalum nitride/tantalum bilayer, tungsten nitride, titanium nitride, tantalum silicon nitride, tungsten silicon nitride, titanium silicon nitride, and the like. If the barrier layer 312 is comprised of tantalum nitride/tantalum bilayer, a physical vapor deposition process may be used to form the barrier layer 312. In some embodiments, the barrier layer 312 is deposited to a thickness in the range from about 10 to about 50 nanometers (nm).

In some embodiments, the barrier layer 312 that is on top of the insulation layer 306 (but not in the interconnect recess 311) may be planarized using, for example, a chemical mechanical polishing (CMP) process. In various embodiments, the width 314 of the interconnect recess 311 after the barrier layer 312 has been deposited is less than 100 nm. For the embodiments, the aspect ratio of the interconnect recess 310, which is the width 314 divided by the height 316 of the interconnect recess 310, may be between 2 to 9.

In various embodiments, a conductive seed film (herein “seed film”) 314 may be deposited or formed on the barrier layer 312 at block 212 (see FIG. 3E). The seed film 314 may be provided as a preparation for plating techniques, such as electroplating and electroless plating. In one embodiment, the conductive seed film 314 is comprised of a conductive material, such as copper, that is formed by, for example, a chemical vapor deposition (CVD) or a physical vapor deposition (PVD) technique. In various embodiments, an overhang 316 or a buildup of seed film material may form at the mouth of the interconnect recess 311 even though the seed film material may be conformal or near conformal.

Once the seed film 314 has been deposited, an interconnect material 318 may be deposited or formed in the interconnect recess 311 and on the top of the insulation layer 306 using, for example, an electroplating process at block 214 (see FIG. 3F) in accordance with some embodiments. Since the introduction of the copper dual-damascene process technology several years ago, electroplating has generally been the method used in the dual-damascene process for depositing a conductive interconnect material onto a wafer. The electroplating operation basically involves electrochemically depositing copper or any other conductive material on to the surface of a, for example, wafer. The whole surface of the wafer, such as described previously, may be covered with a seed layer that serves as a cathode electrode in the electroplating cell of the electroplating system.

For these embodiments, the electroplating process may be carried out, for example, by immersing or contacting the die or wafer (that the interconnect is being formed on) with an aqueous solution containing metal ions, such as copper sulfate-based solution, and reducing the ions onto a cathodic surface. Various metals such as tungsten (W), copper (Cu), silver (Ag), gold (Au), aluminum (Al) and their alloys may be used as the interconnect material 318. In addition, copper alloys such as copper-magnesium, copper-nickel, copper-tin, copper-indium, copper-cadmium, copper-zinc, copper-bismuth, copper-ruthenium, copper-tungsten, copper-cobalt, copper-palladium, copper-gold, copper-platinum, and copper-silver may also be used instead. As a result of the electroplating process, a nonplanarized interconnect 320 is formed. The excess interconnect material on top of the insulation layer 306 is called an overburden 322.

As a result of the formation of the seed film overhang 316, a void (or seam) 324 may form within the interconnect 320. When an interconnect has a width greater than about 110 nm (or bottom widths greater than 90 nm), such void formation may be avoided using several techniques. For example, one approach is to add organic additives to the electrolyte solution that is used to deposit the conductive interconnect material into the interconnect recess to assure proper gap fill of the interconnect recess. Another approach is to optimize the electrical waveform used during the electroplating process. In yet another approach is to improve the seed film profile so that overhangs are not formed and/or widening the interconnect features (e.g., interconnect width). These approaches for preventing void formation in interconnects may, however, be only marginally effective when, for example, the interconnects being formed have small dimensions and/or have certain characteristics such as high AR values. For example, in interconnects having bottom widths of less than about 90 nm and/or AR values of greater than 3.5, such techniques may be marginally effective.

According to various embodiments, dice or wafers containing small interconnects may be formed with less than 70 percent and in some embodiments, less than 1 percent of the interconnects in the dice or wafers having voids. For these embodiments, the small interconnects, such as copper interconnects, may have a bottom width of less than 90 nm and/or top width of about 105 to 110 nm, and aspect ratios of greater than 3 to 3.5 at least initially after, for example, the electroplating process described above (the bottom width is the width of the interconnect nearest to the base 304 as indicated by ref. 326 and the top width of the interconnect is the width of the mouth of the interconnect as indicated by ref. 328). In various embodiments, such voids may be removed or at least reduced by recrystallizing the interconnects being formed.

In order to substantially or completely eliminate the void 324, according to various embodiments, the interconnect material 318 contained in the interconnect 320 and on top of the insulation layer 306 (e.g., overburden 322) surrounding the interconnect 320 may be recrystallized and reflowed at block 216 (see FIG. 3G). For the embodiments, recrystallization of the interconnect material 318 contained in the interconnect recess 311 (as well as the overburden 322 surrounding the interconnect 320) may occur by locally annealing the interconnect material contained in and around the interconnect 320. In various embodiments, such recrystallization may occur when the interconnect material 318 is heated so as to elevate its temperature. The temperature at which the interconnect material 318 recrystallizes will, of course, depend on several factors including, for example, the composition of the interconnect material 318. For example, in some embodiments, copper is used as the interconnect material 318 and recrystallization of the copper interconnect material may occur at temperatures above 200 degrees Celsius. In other embodiments, recrystallization may occur at less than 200 degrees Celsius.

According to some embodiments, rapid laser annealing may be used in order to perform the localized annealing. In rapid laser annealing, a laser may direct electromagnetic radiation 330 (e.g., coherent light) to the interconnect material being annealed for a relatively short time duration in order to recrystallize the interconnect material contained in the interconnect 320. The recrystallization of the interconnect material 318 may reflow the interconnect material 318 thus eliminating or reducing the void 324 according to these embodiments. In various embodiments, the laser may be but is not limited to a Yttrium-Aluminum-Garnet (YAG) laser, a CO₂ laser, an Ar+ laser, and the like.

The wavelength of the coherent light that is generated by the laser may depend upon a number of factors including, for example, the type of laser being used, the power level, the type of interconnect material being annealed, the annealing time, and the like. For example, in one embodiment, a YAG laser is employed that generates coherent light with wavelengths of about 1.064 nm. In another embodiment, the laser is a CO₂ laser that generates coherent light with wavelengths of about 10.6 microns. In yet another embodiment, the laser is an Ar+ laser that generates coherent light with wavelengths of about 514 nm to about 488 nm. The wavelengths provided above are for illustrative purposes only and should not be considered limiting. As described previously, a number of factors may influence which wavelengths to be used. Thus, a wide range of wavelengths may be used.

The annealing time may also vary depending on a number of factors including but are not limited to the type of laser used, laser power, wavelength, composition of the interconnect material, and the like. In some embodiments, the annealing time may be about 30 to about 60 μsec. According to some embodiments, a CO₂ laser with power of about 50 to about 200 Watts (W) is used. For the embodiment, the anneal time may range from about 1 to about 200 μsec.

If the interconnect being recrystallized is a trench or trench line then in various embodiments, the laser may direct coherent light along the trench line. That is, a laser may direct coherent light along trench metal lines (as depicted in FIG. 1B) in order to selectively heat the trench metal lines without excessively heating surrounding materials such as the insulation layer 306 surrounding the interconnect. For example, in FIG. 1B, the laser may initially focus its coherent light beam at one end of the trench 106 as indicated by ref. 117 and trace the trench 106 until the coherent light beam ends up at the other end of the trench 106 as indicated by ref. 118. For these embodiments, a laser may be employed that is coupled to a control system that includes a processor. The control system may further be coupled to a storage device that may include digitized data that may define a predefined path for the light beam to follow. Based on this digitized data, the control system may direct the laser along the predefined path that may correspond to the trench or metal line to be recrystallized.

After the interconnect material contained in the interconnect recess has been recrystallized and the void or seam has been eliminated or reduced, a planarization process may be performed at block 218 (see FIG. 3H) to remove the excess overburden 322 from the top of the insulation layer 306. Such a process may further remove the barrier layer 312 on top of the insulation layer 306 as well as a top portion of the insulation layer 306. In one embodiment, a chemical mechanical polishing process may be employed to remove the excess overburden 322. In other embodiments, other processes may be employed to remove the excess overburden 322. As a result of the planarization process, a planarized interconnect 332 is formed.

Once the planarization process has been completed, a determination may be made as to whether to form another ILD layer with another recrystallized interconnect at block 220. If another ILD layer containing another recrystallized interconnect is to be formed then the process 200 is repeated. If not, then the process 200 ends.

Note that the blocks 202 to 220 illustrated in FIG. 2 may be modified or be in a different sequential order than the one depicted in various other embodiments. For example, the recrystallization block 216 may be performed after the planarization block 218 in some embodiments. Further, in some embodiments, one or more of the blocks 202 to 218 may be eliminated from the overall process 200. Yet further, other block or blocks of operation may be added in various other embodiments.

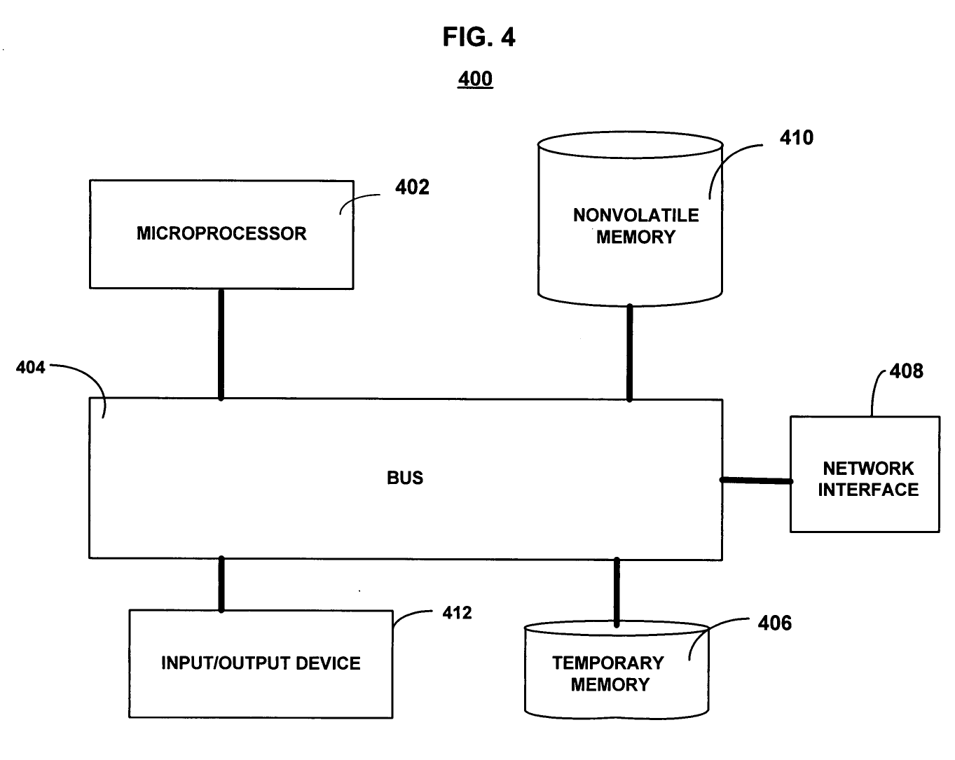

Referring now to FIG. 4, where a system 400 in accordance with some embodiments is shown. The system 400 includes a microprocessor 402 that may be coupled to a bus 404. The system 400 may further include temporary memory 406, a network interface 408, an optional nonvolatile memory 410 (such as a mass storage device) and an input/output (I/O) device interface unit 412. In some embodiments, the input/output device interface unit 412 may be adapted to interface a keyboard, a cursor control device, and/or other devices. One or more of the above enumerated elements, such as microprocessor 402, temporary memory 406, nonvolatile memory 410, and so forth, may include the novel voidless or substantially voidless interconnects described above.

Depending on the applications, the system 400 may include other components, including but not limited to chipsets, RF transceivers, mass storage (such as hard disk, compact disk (CD)), digital versatile disk (DVD), graphical or mathematic co-processors, and so forth.

One or more of the system components may be located on a single chip such as a system on chip (SOC). In various embodiments, the system 400 may be a personal digital assistant (PDA), a wireless mobile phone, a tablet computing device, a laptop computing device, a desktop computing device, a set-top box, an entertainment control unit, a digital camera, a digital video recorder, a media recorder, a media player, a CD player, a DVD player, a network server, or device of the like.

Although specific embodiments have been illustrated and described herein, it will be appreciated by those of ordinary skill in the art that any arrangement which is calculated to achieve the same purpose may be substituted for the specific embodiment shown. This application is intended to cover any adaptations or variations of the embodiments of the present invention. Therefore, it is manifestly intended that this invention be limited only by the claims.

1. A method, comprising:
providing a first insulation layer on a die; and
forming an interconnect in the insulation layer, including recrystallizing the interconnect to reduce void space in the interconnect.

2. The method of claim 1, wherein said forming comprises forming an interconnect with a bottom width of less than about 90 nanometers.

3. The method of claim 2, wherein said forming comprises forming an interconnect having an aspect ratio of greater than 2.0.

4. The method of claim 1, wherein said forming comprises depositing a seed layer into an interconnect recess and depositing conductive material into the interconnect recess on top of the seed layer.

5. The method of claim 1, wherein said forming comprises rapid laser annealing the interconnect to recrystallize the interconnect.

6. The method of claim 5, wherein said rapid laser annealing comprises laser annealing using a laser selected from the laser group consisting of a YAG laser, a CO₂ laser and an Ar+ laser.

7. The method of claim 5, wherein said rapid laser annealing comprises laser annealing using a CO₂ laser operating at about 50 to about 200 Watts and the annealing time is in the range of about 1 to about 200 μsec.

8. The method of claim 1, wherein said forming comprises depositing a metal selected from the metal group consisting of Cu, W, Au, Ag, Al, Cu alloy, W alloy, Au alloy, and Al alloy, into an interconnect recess.

9. The method of claim 1, further comprises forming a second insulation layer on the first insulation layer on the die and forming a second interconnect in the second insulation layer, including recrystallizing the second interconnect to reduce void space in the second interconnect.

10. A die, comprising:
an insulation layer; and
a plurality of interconnects in the insulation layer, the plurality of interconnects having bottom widths of less than about 90 nanometers, and less than 70 percent of the plurality of interconnects having voids.

11. The die of claim 10, wherein less than 1 percent of the plurality of interconnects having voids.

12. The die of claim 10, wherein the plurality of interconnects comprises a metal selected from the metal group consisting of Cu, W, Au, Ag, Al, Cu alloy, W alloy, Au alloy, and Al alloy.

13. The die of claim 10, wherein the plurality of interconnects are selected from the group consisting of vias and trenches.

14. The die of claim 10, wherein the plurality of interconnects have aspect ratios of greater than 2.0.

15. The die of claim 10, wherein the plurality of interconnects have been recrystallized by laser annealing.

16. A system, comprising:
a die, including
an insulation layer; and
a plurality of interconnects in the insulation layer, the plurality of interconnects having bottom widths of less than about 90 nanometers, and less than 70 percent of the plurality of interconnects having voids;
a bus coupled to the die; and
a mass storage coupled to the bus.

17. The system of claim 16, wherein less than 1 percent of the plurality of interconnects having voids.

18. The system of claim 16, wherein the plurality of interconnects have aspect ratios of greater than 2.0.

19. The system of claim 16, wherein the plurality of interconnects has been recrystallized by laser annealing.

20. The system of claim 16, wherein the system further comprises an input/output device interface unit adapted to interface at least a selected one of a keyboard and a cursor control device.

21. The system of claim 16, wherein the system is a selected one of a set-top box, a digital camera, a CD player, or a DVD player.
